(19) United States
(12) Patent Application Publication
(10) Pub. No.: US 2009/0096491 A1
(43) Pub. Date: Apr. 16, 2009

(54) DRIVER CIRCUIT, DATA DRIVER, INTEGRATED CIRCUIT DEVICE, AND ELECTRONIC INSTRUMENT

(75) Inventor: Motoaki NISHIMURA, Fujimi-machi (JP)

Correspondence Address: OLIFF & BERRIDGE, PLC, P.O. BOX 320850, ALEXANDRIA, VA, 22320-4850, US

(73) Assignee: Seiko Epson Corporation, Tokyo (JP)

(21) Appl. No.: 12/250,934

(22) Filed: Oct. 14, 2008

(30) Foreign Application Priority Data
Oct. 15, 2007 (JP) 2007-267768
May 23, 2008 (JP) 2008-135605

(51) Int. Cl. H03K 3/00

(52) U.S. Cl. 327/108

(57) ABSTRACT

A driver circuit includes a first capacitor provided between a first node and a reference node, a second capacitor provided between a second node and the reference node, a first switch element provided between the first node and an input node, a second switch element provided between the first node and an analog reference power supply, a third switch element provided between the second node and an output node, a fourth switch element provided between the second node and the analog reference power supply, and a fifth switch element provided between the output node and the reference node. A first capacitor area and a second capacitor area are disposed along a first direction. The first switch element and the second switch element are disposed in a third direction with respect to the first capacitor area and the second capacitor area. The third switch element and the fourth switch element are disposed in the first direction with respect to the first capacitor area and the second capacitor area. A reference node line is provided in a second direction with respect to the first switch element, the second switch element, the third switch element, and the fourth switch element.

Japanese Patent Application No. 2007-267768 filed on Oct. 15, 2007 and Japanese Patent Application No. 2008-135605 filed on May 23, 2008, are hereby incorporated by reference in their entirety.

### BACKGROUND

The present invention relates to a driver circuit, a data driver, an integrated circuit device, an electronic instrument, and the like.

As a liquid crystal panel (electro-optical device or display panel) used for electronic instruments such as portable telephones, a simple matrix liquid crystal panel and an active matrix liquid crystal panel that utilizes a switch element such as a thin film transistor have been known.

In recent years, the number of data lines (source lines) of a liquid crystal panel has increased along with an increase in the screen size and the number of pixels. On the other hand, an increase in accuracy of a voltage applied to each data line has been desired. A reduction in power consumption and chip size of a driver circuit that drives data lines of a liquid crystal panel has also been desired along with a demand for a reduction in weight and size of battery-driven electronic instruments provided with a liquid crystal panel. JP-A-2005-175811 and JP-A-2005-175812 disclose a related-art driver circuit that drives the data lines of a liquid crystal panel, for example.

However, a related-art driver circuit has a problem in that the voltage output to the data line varies due to an offset voltage of an operational amplifier. In order to solve such a problem, a DAC drive operation that directly drives the data line using a D/A conversion circuit in the latter half of the drive period has been employed, for example. However, the drive period becomes insufficient when performing the DAC drive operation. This makes it difficult to deal with a multiplex drive operation that drives a plurality of data lines using one driver circuit, for example.

In order to accurately drive the data line, it is necessary to contrive a layout method for each circuit of the driver circuit. However, JP-A-2005-175811 and JP-A-2005-175812 do not disclose a specific example of such a layout method.

### SUMMARY

According to one aspect of the invention, there is provided a driver circuit that receives an input voltage and outputs an output voltage, the driver circuit comprising;

a first capacitor provided between a first node and a reference node;

a first switch element provided between the first node and an input node of the input voltage;

a second switch element provided between the first node and an analog reference power supply;

a second capacitor provided between a second node and the reference node;

a third switch element provided between the second node and an output node of the output voltage;

a fourth switch element provided between the second node and the analog reference power supply; and

a fifth switch element provided between the output node and the reference node,

a first capacitor area and a second capacitor area being disposed along a first direction, the first capacitor being formed in the first capacitor area, and the second capacitor being formed in the second capacitor area;

the first switch element and the second switch element being disposed in a third direction with respect to the first capacitor area and the second capacitor area, the third direction being a direction opposite to the first direction;

the third switch element and the fourth switch element being disposed in the first direction with respect to the first capacitor area and the second capacitor area; and

a reference node line that is a line of the reference node being provided in a second direction with respect to the first switch element, the second switch element, the third switch element, and the fourth switch element, the second direction being a direction that perpendicularly intersects the first direction.

According to another aspect of the invention, there is provided a driver circuit that receives an input voltage and outputs an output voltage, the driver circuit comprising:

a first capacitor, one end of the first capacitor being connected to a reference node, and the other end of the first capacitor being set at a voltage supplied from an analog reference power supply in an initialization period and set at the input voltage in an output period; and

a second capacitor, one end of the second capacitor being connected to the reference node, and the other end of the second capacitor being set at the voltage supplied from the analog reference power supply in the initialization period and set at the output voltage in the output period,

a reference node line that is a line of the reference node being provided along a first direction;

a first analog reference power supply line being provided along a second direction in a third direction with respect to a first capacitor area and a second capacitor area, the first analog reference power supply line supplying the voltage supplied from the analog reference power supply to the other end of the first capacitor, a direction that perpendicularly intersects the first direction being referred to as the second direction and a direction opposite to the first direction being referred to as the third direction; and

a second analog reference power supply line being provided along the second direction in the first direction with respect to the first capacitor area and the second capacitor area, the second analog reference power supply line supplying the voltage supplied from the analog reference power supply to the other end of the second capacitor.

According to another aspect of the invention, there is provided a data driver that drives a data line of an electro-optical device, the data driver comprising:

a D/A conversion circuit that receives grayscale data and outputs a grayscale voltage corresponding to the grayscale data; and

the above driver circuit that receives the grayscale voltage output from the D/A conversion circuit as the input voltage, and outputs the output voltage to the data line.

According to another aspect of the invention, there is provided an integrated circuit device comprising the above data driver.

According to another aspect of the invention, there is provided an electronic instrument comprising the above integrated circuit device.

### BRIEF DESCRIPTION OF THE DRAWINGS

FIG. 1 shows a configuration example of a driver circuit according to one embodiment of the invention.

FIG. 2 shows a configuration example of a driver circuit according to one embodiment of the invention.

FIG. 3 shows a signal waveform example illustrative of the operation of a driver circuit.

FIGS. 4A, 4B and 4C are fundamental configuration diagrams showing a driver circuit according to one embodiment of the invention.

FIG. 5 shows a layout example of a driver circuit.

FIGS. 6A and 6B show layout examples of capacitor areas.

FIG. 7 shows a layout example of a driver circuit.

FIG. 8 shows a modification of a driver circuit according to one embodiment of the invention.

FIG. 9 shows a modification of a driver circuit according to one embodiment of the invention.

FIG. 10 shows a configuration example of an operational amplifier.

FIG. 11 shows a layout example of a driver circuit according to a modification.

FIG. 12 shows a configuration example of an integrated circuit device according to one embodiment of the invention.

FIG. 13 shows a configuration example of a data driver according to one embodiment of the invention.

FIG. 14 is a view illustrative of the operation of a data driver.

FIG. 15 shows a configuration example of a D/A conversion circuit.

FIGS. 16A and 16B show configuration examples of an electronic instrument.

### DESCRIPTION OF EXEMPLARY EMBODIMENTS

Several aspects of the invention may provide a driver circuit, a data driver, an integrated circuit device, and an electronic instrument that can output an accurate voltage by minimizing an adverse effect of a parasitic capacitance and the like.

According to one embodiment of the invention, there is provided a driver circuit that receives an input voltage and outputs an output voltage, the driver circuit comprising:

a first capacitor provided between a first node and a reference node;

a first switch element provided between the first node and an input node of the input voltage;

a second switch element provided between the first node and an analog reference power supply;

a second capacitor provided between a second node and the reference node;

a third switch element provided between the second node and an output node of the output voltage;

a fourth switch element provided between the second node and the analog reference power supply; and

a fifth switch element provided between the output node and the reference node,

a first capacitor area and a second capacitor area being disposed along a first direction, the first capacitor being formed in the first capacitor area, and the second capacitor being formed in the second capacitor area;

the first switch element and the second switch element being disposed in a third direction with respect to the first capacitor area and the second capacitor area, the third direction being a direction opposite to the first direction;

the third switch element and the fourth switch element being disposed in the first direction with respect to the first capacitor area and the second capacitor area; and

a reference node line that is a line of the reference node being provided in a second direction with respect to the first switch element, the second switch element, the third switch element, and the fourth switch element, the second direction being a direction that perpendicularly intersects the first direction.

According to this embodiment, since the first switch element and the second switch element are disposed in the third direction with respect to the first capacitor area, the input voltage from a circuit in the preceding stage can be supplied to the first switch element and the second switch element along a short path. Since the third switch element and the fourth switch element are disposed in the first direction with respect to the second capacitor area, a circuit in the subsequent stage can be connected to the third switch element and the fourth switch element along a short path. Therefore, the layout efficiency can be improved while minimizing a parasitic capacitance that adversely affects the performance. According to this embodiment, the reference node line is provided in the second direction with respect to the first to fourth switch elements. Therefore, the distance between the line connected to the first or second node and the reference node line can be increased so that an adverse effect due to a parasitic capacitance between these nodes can be minimized.

The driver circuit may further comprise:

a first analog reference power supply line provided along the second direction in the third direction with respect to the first capacitor area and the second capacitor area, the first analog reference power supply line supplying a voltage supplied from the analog reference power supply to the second switch element; and

a second analog reference power supply line provided along the second direction in the first direction with respect to the first capacitor area and the second capacitor area, the second analog reference power supply line supplying the voltage supplied from the analog reference power supply to the fourth switch element.

The voltage supplied from the analog reference power supply can be supplied to the second switch element and the fourth switch element along a short path by thus providing the first analog reference power supply line and the second analog reference power supply line, for example. Moreover, the area inside the first analog reference line and the second analog reference line can be shielded from the outer area. This prevents a situation in which a change in voltage in the outer area is transmitted to the reference node through a parasitic capacitor to adversely affect the circuit characteristics.

In the driver circuit,

the second switch element, the fourth switch element, and the fifth switch element may be turned ON in an initialization period; and

the first switch element and the third switch element may be turned ON in an output period of the output voltage.

A charge can be stored in the first capacitor and the second capacitor in the initialization period, and the output voltage corresponding to the input voltage can be output to the output node in the output period by thus controlling the first to fifth switch elements.

The driver circuit may further comprise:

an operational amplifier that outputs the output voltage to the output node, a first input terminal of the operational amplifier being connected to the reference node, and a second input terminal of the operational amplifier being set at a voltage supplied from the analog reference power supply.

The reference node can be set at the voltage supplied from the analog reference power supply in the initialization period due to the virtual short-circuit function of the operational amplifier, and the drive target can be driven in the output period by utilizing the impedance conversion function of the operational amplifier.

The driver circuit may further comprise:

an oscillation prevention capacitor, one end of the oscillation prevention capacitor being electrically connected to the output node of the operational amplifier in an initialization period to prevent oscillation of the operational amplifier.

According to this configuration, even if the load of the driver circuit decreases in the initialization period, for example, oscillation of the operational amplifier can be prevented by electrically connecting the oscillation prevention capacitor to the output node.

In the driver circuit,

the fifth switch element may be disposed in the second direction with respect to the third switch element and the fourth switch element; and

a dummy switch element of the fifth switch element may be disposed in the second direction with respect to the first switch element and the second switch element.

This implements a symmetrical layout so that deterioration in circuit characteristics can be prevented.

In the driver circuit may further comprise:

an auxiliary capacitor, one end of the auxiliary capacitor being connected to the reference node, and

the auxiliary capacitor may be formed in a capacitor area between the first capacitor area and the second capacitor area.

According to this configuration, a change in the voltage of the reference node can be suppressed. Moreover, the capacitors can be arranged symmetrically so that deterioration in circuit characteristics can be prevented.

According to another embodiment of the invention, there is provided a driver circuit that receives an input voltage and outputs an output voltage, the driver circuit comprising:

a first capacitor, one end of the first capacitor being connected to a reference node, and the other end of the first capacitor being set at a voltage supplied from an analog reference power supply in an initialization period and set at the input voltage in an output period; and

a second capacitor, one end of the second capacitor being connected to the reference node, and the other end of the second capacitor being set at the voltage supplied from the analog reference power supply in the initialization period and set at the output voltage in the output period,

a reference node line that is a line of the reference node being provided along a first direction;

a first analog reference power supply line being provided along a second direction in a third direction with respect to a first capacitor area and a second capacitor area, the first analog reference power supply line supplying the voltage supplied from the analog reference power supply to the other end of the first capacitor, a direction that perpendicularly intersects the first direction being referred to as the second direction and a direction opposite to the first direction being referred to as the third direction; and

a second analog reference power supply line being provided along the second direction in the first direction with respect to the first capacitor area and the second capacitor area, the second analog reference power supply line supplying the voltage supplied from the analog reference power supply to the other end of the second capacitor.

According to this embodiment, since the first analog reference power supply line is provided along the second direction in the third direction with respect to the first capacitor area and the second capacitor area and the second analog reference power supply line is provided along the second direction in the first direction with respect to the first capacitor area and the second capacitor area, the area inside the first analog reference line and the second analog reference line can be shielded from the outer area. This prevents a situation in which a change in voltage in the outer area is transmitted to the reference node through a parasitic capacitor to adversely affect the circuit characteristics, for example.

According to another embodiment of the invention, there is provided a data driver that drives a data line of an electro-optical device, the data driver comprising:

a D/A conversion circuit that receives grayscale data and outputs a grayscale voltage corresponding to the grayscale data; and

one of the above driver circuits that receives the grayscale voltage output from the D/A conversion circuit as the input voltage, and outputs the output voltage to the data line.

According to another embodiment of the invention, there is provided an integrated circuit device comprising the above data driver.

According to another embodiment of the invention, there is provided an electronic instrument comprising the above integrated circuit device.

Preferred embodiments of the invention are described in detail below. Note that the following embodiments do not in any way limit the scope of the invention defined by the claims laid out herein. Note that all elements of the following embodiments should not necessarily be taken as essential requirements for the invention.

1. Driver Circuit

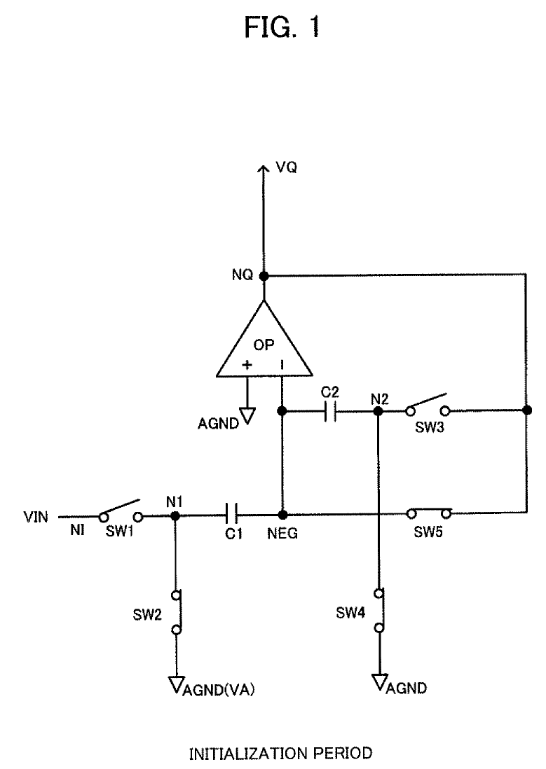

FIG. 1 shows a configuration example of a driver circuit according to one embodiment of the invention. The driver circuit according to this embodiment is not limited to the configuration shown in FIG. 1. Various modifications may be made such as omitting some (e.g., operational amplifier) of the elements or adding other elements.

The driver circuit shown in FIG. 1 is a circuit that receives an input voltage VIN, outputs an output voltage VQ, and drives a drive target (e.g., data line). The driver circuit includes first and second capacitors C1 and C2 and first to fifth switch elements SW1 to SW5. The driver circuit may include an operational amplifier OP.

The capacitor C1 is provided between a reference node NEG (negative node, inverting input terminal node, or charge storage node) and a first node N1. The capacitor C2 is provided between the reference node NEG and a second node N2. Each of the capacitors C1 and C2 may be formed by a plurality of unit capacitors, for example.

The switch element SW1 is provided between the node N1 and an input node NI of the input voltage VIN. The switch element SW2 is provided between the node N1 and a power supply AGND (analog reference power supply in a broad sense). The switch element SW3 is provided between the node N2 and an output node NQ. The switch element SW4 is provided between the node N2 and the power supply AGND (AGND node). The switch element SW5 is provided between the reference node NEG and the output node NQ.

The switch elements SW1 to SW5 may be formed by CMOS transistors, for example. Specifically, the switch elements SW1 to SW5 may be formed by transfer gates including a P-type transistor and an N-type transistor. These transistors are turned ON/OFF based on switch control signals output from a switch control signal generation circuit (not shown). The voltage supplied from the power supply AGND is an intermediate voltage between a high-potential-side power supply VDD (second power supply) and a low-potential-side power supply VSS (first power supply) (e.g., AGND=(VDD+VSS)/2), for example.

An inverting input terminal (first input terminal in a broad sense) of the operational amplifier OP is connected to the reference node NEG, and a non-inverting input terminal (second input terminal in a broad sense) of the operational amplifier OP is set at the voltage supplied from the power supply AGND (analog reference power supply). The operational amplifier OP outputs the output voltage VQ to the output node NQ (output terminal).

In the driver circuit according to this embodiment, the switch elements SW2, SW4, and SW5 are turned ON in an initialization period (i.e., a period in which an initialization voltage is set across the capacitors C1 and C2), as shown in FIG. 1.

When the switch element SW2 is turned ON in the initialization period, the other end of the capacitor C1 of which one end is electrically connected to the reference node NEG is set at the voltage supplied from the power supply AGND (analog reference power supply voltage VA). Likewise, when the switch element SW4 is turned ON, the other end of the capacitor C2 of which one end is electrically connected to the reference node NEG is set at the voltage supplied from the power supply AGND (VA). When the switch element SW5 (i.e., feedback switch element) is turned ON, the output from the operational amplifier OP is fed back to the inverting input terminal, and the node NEG is set at the voltage supplied from the power supply AGND due to the virtual short-circuit function of the operational amplifier OP.

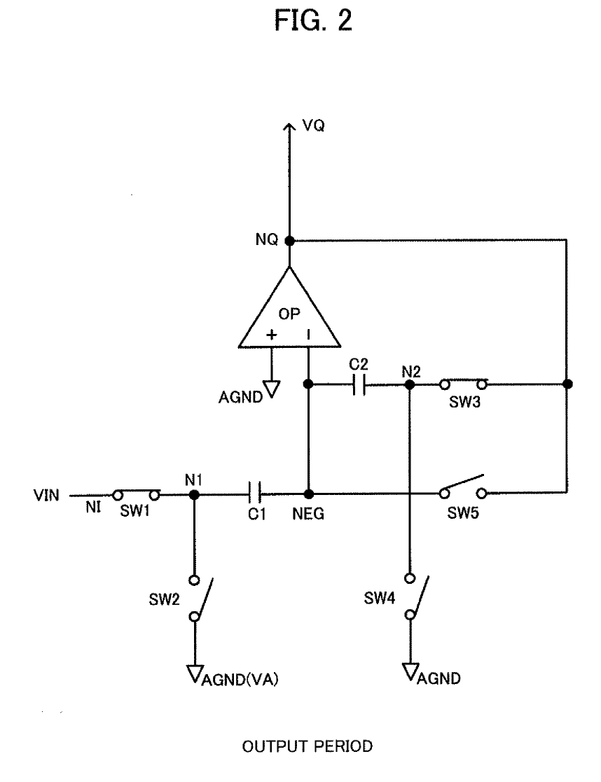

In the driver circuit according to this embodiment, the switch elements SW1 and SW3 are turned ON in an output period (i.e., a period in which the output voltage is output to drive the drive target), as shown in FIG. 2.

When the switch element SW1 is turned ON in the output period, the other end of the capacitor C1 of which one end is electrically connected to the reference node NEG is set at the input voltage VIN. When the switch element SW3 is turned ON, the other end of the capacitor C2 of which one end is electrically connected to the reference node NEG is set at the output voltage VQ (output from the operational amplifier OP).

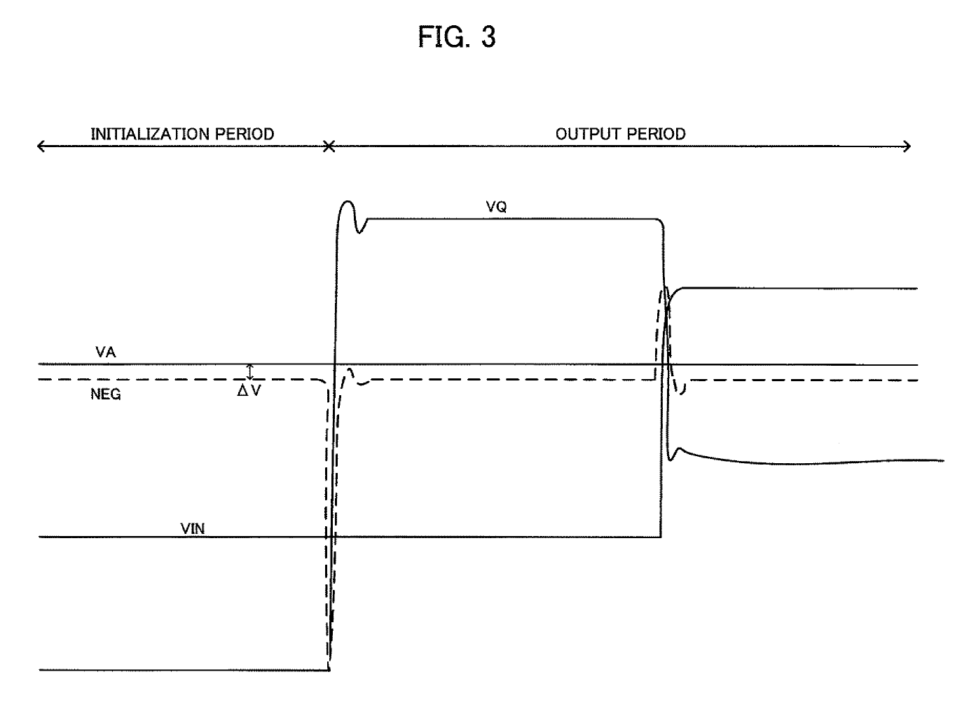

FIG. 3 shows a signal waveform example illustrative of the operation according to this embodiment. In FIG. 3, VA indicates the voltage supplied from the power supply AGND (e.g., VA=(VDD+VSS)/2). Note that the voltage VA is a voltage between the high-potential-side power supply voltage VDD and the low-potential-side power supply voltage VSS, and is not limited to (VDD+VSS)/2.

In the initialization period shown in FIG. 1, since the feedback switch element SW5 is turned ON, the node NEG of the inverting input terminal of the operational amplifier OP is set at a voltage equal to the voltage VA (i.e., the voltage supplied from the power supply AGND) of the non-inverting input terminal due to the virtual short-circuit function of the operational amplifier OP. Since the operational amplifier OP has an offset due to a process variation and the like, the voltage of the node NEG and the voltage VA differ by an offset voltage ΔV, as shown in FIG. 3.

In the driver circuit according to this embodiment, the offset voltage ΔV is stored in the initialization period shown in FIG. 1, and the offset voltage ΔV is canceled and the output voltage VQ is output in the output period shown in FIG. 2. Therefore, an offset-free state can be implemented.

In the output period, the output voltage VQ changes toward the low potential side (VSS side) when the input voltage VIN changes toward the high potential side (VDD side), and changes toward the high potential side when the input voltage VIN changes toward the low potential side, as shown in FIG. 3.

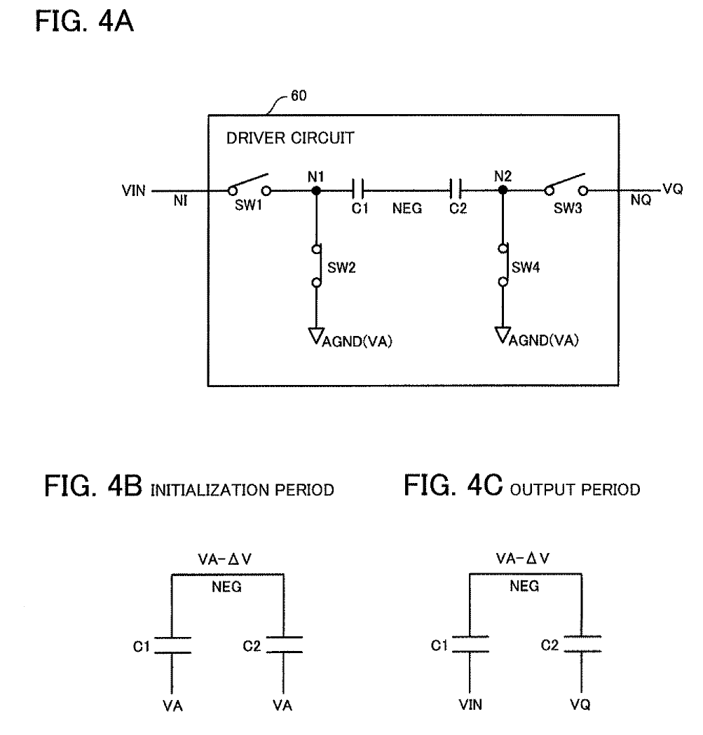

FIG. 4A shows a fundamental configuration of the driver circuit according to this embodiment. As shown in FIG. 4A, a driver circuit 60 according to this embodiment includes the capacitor C1, one end of the capacitor C1 being connected to the reference node NEG, and the other end of the capacitor C1 being set at the analog reference voltage VA in the initialization period and set at the input voltage VIN in the output period. The driver circuit 60 includes the capacitor C2, one end of the capacitor C2 being connected to the reference node NEG, and the other end of the capacitor C2 being set at the analog reference voltage VA in the initialization period and set at the output voltage VQ in the output period.

The reference node NEG (connection node of the capacitors C1 and C2) is a node that is set at a given voltage (e.g., VA or VA−ΔV) in the initialization period and is set in a high impedance state (floating state) in the output period. In FIGS. 1 and 2, the function of the node NEG is implemented by utilizing the operational amplifier OP. Note that the function of the node NEG may be implemented by a circuit other than the operational amplifier OP.

The relationship between the input voltage VIN and the output voltage VQ in the driver circuit according to this embodiment is described below with reference to FIGS. 4B and 4C.

In the initialization period, one end of the capacitors C1 and C2 is set at the voltage VA, and the other end of the capacitors C1 and C2 is set at VA−ΔV, as shown in FIG. 4B. Note that ΔV is the offset voltage of the operational amplifier OP.

In the output period, one end of the capacitor C1 is set at the input voltage VIN, the other end of the capacitor C1 is set at VA−ΔV, one end of the capacitor C2 is set at the output voltage VQ, and the other end of the capacitor C2 is set at VA−ΔV, as shown in FIG. 4C. Therefore, the following equation is satisfied according to the principle of charge conservation.

C1×{(VA−(VA−ΔV)}+C2×{(VA−(VA−ΔV)}=C1×{VIN−(VA−ΔV)}+C2×{VQ−(VA−ΔV)} (1)

Therefore, the following equation is satisfied.

VQ=VA−(C1/C2)×(VIN−VA) (2)

As is clear from the equation (2), since the offset voltage ΔV is not involved in the output voltage VQ, an offset-free state can be implemented.

For example, a driver circuit according to a comparative example of this embodiment stores a charge corresponding to an input voltage using a sampling capacitor in a sampling period, and performs a flip-around operation of the sampling capacitor in a holding period to output a voltage corresponding to the stored charge.

However, since the output of the driver circuit according to the comparative example is set in a high impedance state in the sampling period, a loss in drive time occurs.

On the other hand, the driver circuit according to this embodiment can successively output the output voltage VQ by utilizing the two capacitors C1 and C2. Specifically, since the output voltage VQ corresponding to the input voltage VIN is output according to the equation (2) (i.e., the sampling period is not provided) in the output period after the initialization period, the drive target can be driven successively.

2. Layout

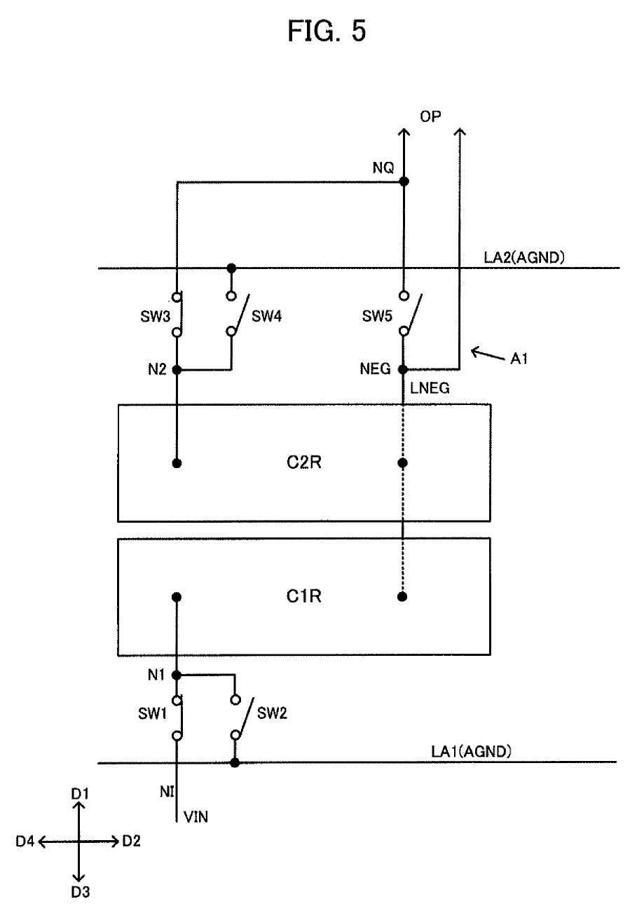

FIG. 5 shows a layout example of the driver circuit according to this embodiment. In FIG. 5, a direction opposite to a first direction D1 is a third direction D3, a direction that perpendicularly intersects the first direction D1 is a second direction D2, and a direction opposite to the second direction D2 is a fourth direction D4.

In FIG. 5, a first capacitor area C1R in which the capacitor C1 shown in FIGS. 1 and 2 is formed and a second capacitor area C2R in which the capacitor C2 is formed are disposed along the direction D1. Note that a modification in which the capacitor areas C1R and C2R are disposed along the direction D2 is also possible.

The switch elements SW1 and SW2 are disposed in the direction D3 with respect to the capacitor areas C1R and C2R. The switch elements SW3 and SW4 are disposed in the direction D1 with respect to the capacitor areas C1R and C2R. The switch element SW5 is disposed in the direction D2 with respect to the switch elements SW3 and SW4.

A line LNEG connected to the reference node NEG is provided in the direction D2 with respect to the switch elements SW1, SW2, SW3, and SW4. Specifically, the line LNEG (at least part of the line LNEG; a connection line in an upper layer of a wiring layer that forms the capacitor) is provided along the direction D1 in the direction D2 with respect to the switch elements SW1, SW2, SW3, and SW4.

According to the layout shown in FIG. 5, since the switch elements SW1 and SW2 are disposed in the direction D3 with respect to the capacitor area C1R, the input voltage VIN from a circuit in the preceding stage can be supplied to the switch elements SW1 and SW2 (capacitor C1) along a short path. Since the switch elements SW3 and SW4 are disposed in the direction D1 with respect to the capacitor area C2R, a circuit in the subsequent stage (e.g., operational amplifier) and the switch elements SW3 and SW4 (capacitor C2) can be connected along a short path. Therefore, the layout efficiency can be improved. Moreover, a parasitic capacitance and a parasitic resistance that adversely affect the performance can be minimized.

In FIG. 5, the reference node line LNEG is provided in the direction D2 with respect to the switch elements SW1 to SW4. Therefore, the distance between the line connected to the node N1 or N2 and the reference node line LNEG can be increased. Accordingly, when the parasitic capacitance between the node N1 and the reference node NEG is referred to as CP1 and the parasitic capacitance between the node N2 and the reference node NEG is referred to as CP2, the difference CPD between the parasitic capacitance CP1 and the parasitic capacitance CP2 can be minimized.

Specifically, “C1/C2” in “VQ=VA−(C1/C2)×(VIN−VA)” described using the equation (2) changes when the difference CPD in parasitic capacitance increases, whereby the output voltage VQ changes. Moreover, when driving a plurality of data lines using a plurality of driver circuits (described later), the output voltage VQ varies between the driver circuits due to a process variation, whereby the display quality deteriorates, for example. In this case, an adverse effect of the difference CPD can be eliminated by forming symmetrical wiring lines. However, when an unsymmetrical wiring area as indicated by A1 in FIG. 5 is provided, for example, the effect of the difference CPD cannot be disregarded due to the loss of symmetry.

In FIG. 5, since the distance between the line connected to the node N1 or N2 and the reference node line LNEG can be increased, the absolute values of the parasitic capacitance CP1 between the node N1 and the reference node NEG and the parasitic capacitance CP2 between the node N2 and the reference node NEG can be reduced. Therefore, even if an unsymmetrical area as indicated by A1 is provided, an adverse effect of the difference CPD can be minimized since the absolute value of the difference CPD is small.

According to the layout shown in FIG. 5, when a line that passes between the capacitor areas C1R and C2R along the direction D2 is referred to as a symmetry axis, a layout that is line-symmetrical with respect to the symmetry axis can be implemented. Therefore, an adverse effect of the difference CPD can be further reduced.

In FIG. 5, a first analog reference power supply line LA1 that supplies the voltage supplied from the power supply AGND (analog reference power supply) to the switch element SW2 is provided along the direction D2 in the direction D3 with respect to the capacitor areas C1R and C2R. A second analog reference power supply line LA2 that supplies the voltage supplied from the power supply AGND to the switch element SW4 is provided along the direction D2 in the direction D1 with respect to the capacitor areas C1R and C2R.

The voltage supplied from the power supply AGND can be supplied to the switch elements SW2 and SW4 along a short path by providing the AGND lines LA1 and LA2 as shown in FIG. 5. Moreover, the area inside the lines LA1 and LA2 can be shielded from the outer area by the AGND lines LA1 and LA2. This effectively prevents a situation in which a change in the input voltage VIN at the input node NI or a change in the output voltage is transmitted to the node NEG through a parasitic capacitor to adversely affect the circuit characteristics, for example. Moreover, since the lines LA1 and LA2 can be provided line-symmetrically with respect to the symmetry axis, a line-symmetrical layout can be implemented. Therefore, an adverse effect of the difference CPD and the like can be reduced.

It is desirable to provide a shield line set at the potential of the power supply AGND or the like on the left side, right side, upper side, or lower side of the line LNEG connected to the reference node NEG.

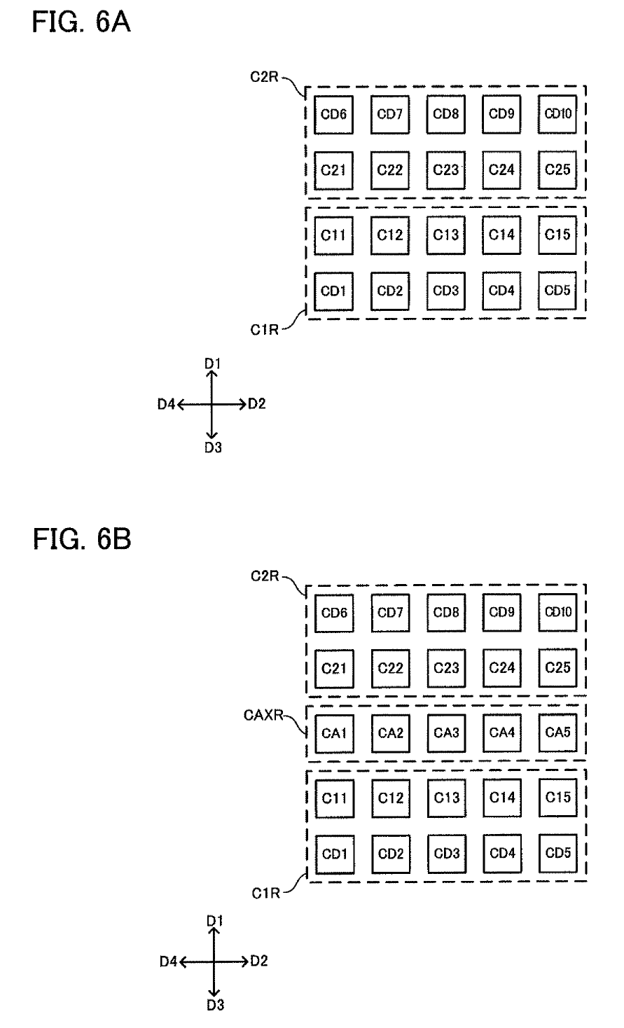

FIG. 6A shows a specific example of the layout of the capacitor areas C1R and C2R. As shown in FIG. 6A, a plurality of unit capacitors C11 to C15 that form the capacitor C1 are disposed in the capacitor area C1R. A plurality of unit capacitors C21 to C25 that form the capacitor C2 are disposed in the capacitor area C2R. The processing accuracy of the capacitor is increased by utilizing the unit capacitors so that the accuracy of the capacitances of the capacitors C1 and C2 can be improved. The unit capacitors may be formed by a metal-insulator-metal (MIM) structure, for example.

In FIG. 6A, dummy unit capacitors CD1 to CD5 are disposed in the direction D3 with respect to the unit capacitors C11 to C15, and dummy unit capacitors CD6 to CD10 are disposed in the direction D1 with respect to the unit capacitors C21 to C25.

For example, when driving a plurality of drive targets using a plurality of driver circuits, the driver circuits may be arranged along the direction D2. In this case, the unit capacitors of the adjacent driver circuits are disposed in the direction D4 and the direction D2 with respect to the unit capacitors C11 to C15 and C21 to C25 in FIG. 6A.

According to the layout shown in FIG. 6A, other unit capacitors can be adjacently disposed around each of the unit capacitors C11 to C15 and C21 to C25. Therefore, since the opening between the edge of one unit capacitor and the edges of the unit capacitors adjacent to that capacitor can be formed at almost the same etching rate, for example, the unit capacitors can be formed with high accuracy so that the accuracy of the capacitance can be improved.

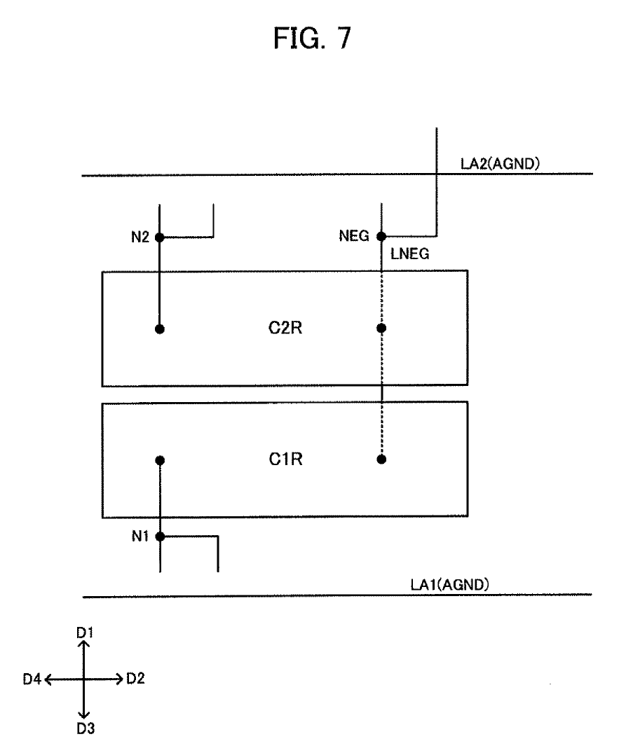

Note that the layout according to this embodiment is not limited to the layout shown in FIG. 5. For example, the switch elements SW1 to SW5 may be disposed in locations differing from those shown in FIG. 5. For example, the switch elements SW1 to SW5 may be disposed in locations differing from those shown in FIG. 5, the AGND line LA1 may be provided along the direction D2 in the direction D3 with respect to the capacitor areas C1R and C2R, and the AGND line LA2 may be provided along the direction D2 in the direction D1 with respect to the capacitor areas C1R and C2R, as shown in FIG. 7. The line LNEG connected to the reference node NEG is provided along the direction D1 in the area shielded by the AGND lines LA1 and LA2, for example.

The layout shown in FIG. 7 also implements a layout that is line-symmetrical with respect to the symmetry axis that passes between the capacitor areas C1R and C2R. Moreover, since the area inside the AGND lines LA1 and LA2 can be shielded from the outer area by the AGND lines LA1 and LA2, an adverse effect of a change in voltage or the like in the outer area on the node NEG can be minimized so that the circuit characteristics can be improved.

3. Modification

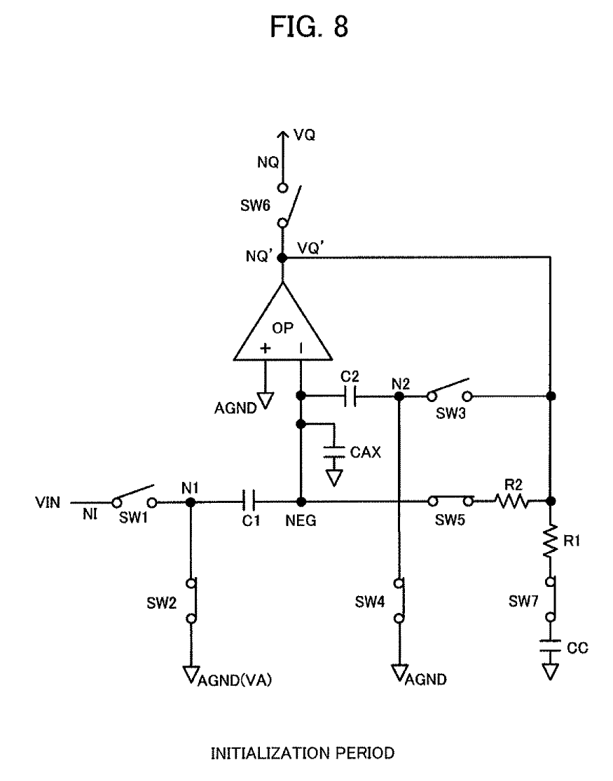

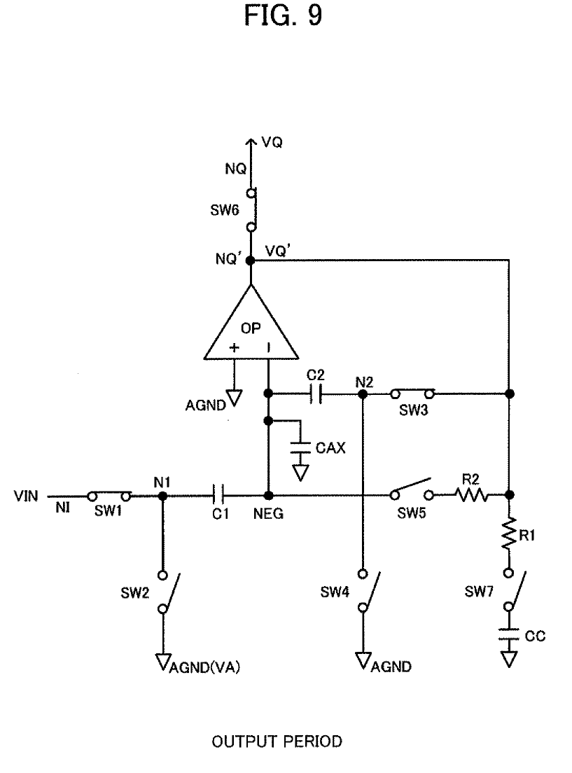

FIGS. 8 and 9 show a modification of the driver circuit according to this embodiment. In FIGS. 8 and 9, an oscillation prevention capacitor CC is provided in addition to the elements shown in FIGS. 1 and 2. In FIGS. 8 and 9, a switch element SW6 that prevents the output voltage from being transmitted to the circuit in the subsequent stage in the initialization period is also provided. The switch element SW6 is turned OFF in the initialization period shown in FIG. 8, and is turned ON in the output period shown in FIG. 9.

In FIGS. 8 and 9, an auxiliary capacitor CAX of which one end is connected to the reference node NEG is also provided. A change in voltage of the node NEG (i.e., the node of the inverting input terminal of the operational amplifier OP) can be suppressed by providing the auxiliary capacitor CAX so that the output voltage VQ can be further stabilized.

Specifically, the voltage of the reference node NEG changes momentarily (see FIG. 2) when a transition from the initialization period shown in FIG. 8 to the output period shown in FIG. 9 occurs. In this case, when the auxiliary capacitor CAX is not provided, the voltage of the reference node NEG changes momentarily by the potential difference between the node N2 and the node NQ (NQ′) when the initialization period has expired. If the voltage of the reference node NEG exceeds the substrate voltage (i.e., VDD or VSS) of the switch element SW5, charges stored in the capacitors C1 and C2 are removed. In FIGS. 8 and 9, the auxiliary capacitor CAX is provided in order to prevent such a phenomenon. According to this configuration, since the capacitor C2 and the capacitor CAX connected in series are provided between the node NQ and the node of the power supply AGND, a change in the voltage of the reference node NEG can be suppressed in the range from the voltage VDD to the voltage VSS so that a situation in which charges stored in the capacitors C1 and C2 are removed can be prevented.

In this embodiment, an amplifier that does not include a phase-compensation capacitor is used as the operational amplifier OP, for example. Specifically, since the switch element SW6 is turned ON in the output period (see FIG. 9), the output of the operational amplifier OP is connected to the drive target (e.g., data line) as a load. Therefore, the load (e.g., 20 pF) functions as a phase-compensation capacitor to prevent oscillation of the operational amplifier OP.

On the other hand, since the switch element SW6 is turned OFF in the initialization period shown in FIG. 8, a load (e.g., data line) is not connected to the operational amplifier OP. Specifically, the load of the operational amplifier OP consists only of the capacitors C1 and C2 and the auxiliary capacitor CAX (e.g., a load of 1 pF). Therefore, the operational amplifier OP may oscillate due to a decrease in load.

In FIGS. 8 and 9, the oscillation prevention capacitor CC of which one end is electrically connected to the output node NQ′ in the initialization period to prevent oscillation of the operational amplifier OP is provided. Specifically, the oscillation prevention capacitor CC and a switch element SW7 are provided between the node NQ′ and the low-potential-side power supply. The switch element SW7 is turned ON in the initialization period shown in FIG. 8 to connect one end of the oscillation prevention capacitor CC to the output node NQ′. In the output period shown in FIG. 9, the switch element SW7 is turned OFF to disconnect one end of the oscillation prevention capacitor CC from the output node NQ′.

Specifically, the oscillation prevention capacitor CC functions as a phase-compensation capacitor in the initialization period in which the load of the operational amplifier OP is reduced so that oscillation of the operational amplifier OP can be effectively prevented. In FIG. 8, oscillation prevention resistors R1 and R2 are also provided.

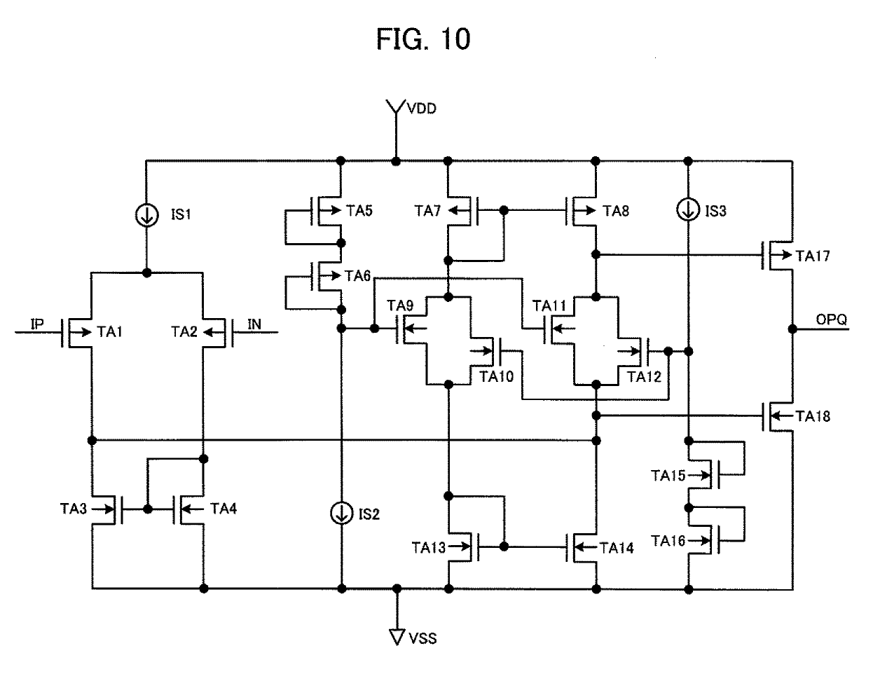

FIG. 10 shows a circuit configuration example of the operational amplifier OP. The operational amplifier OP is an amplifier that performs a class AB amplification operation, and a feed-forward class AB output stage. In FIG. 10, the differential stage of the amplifier is formed by transistors TA1 to TA4 and a current source IS1. The gates of a P-type transistor TA17 and an N-type transistor TA18 that form the output stage are controlled by an auxiliary circuit formed by transistors TA7 to TA14 so that a class AB amplification operation can be implemented.

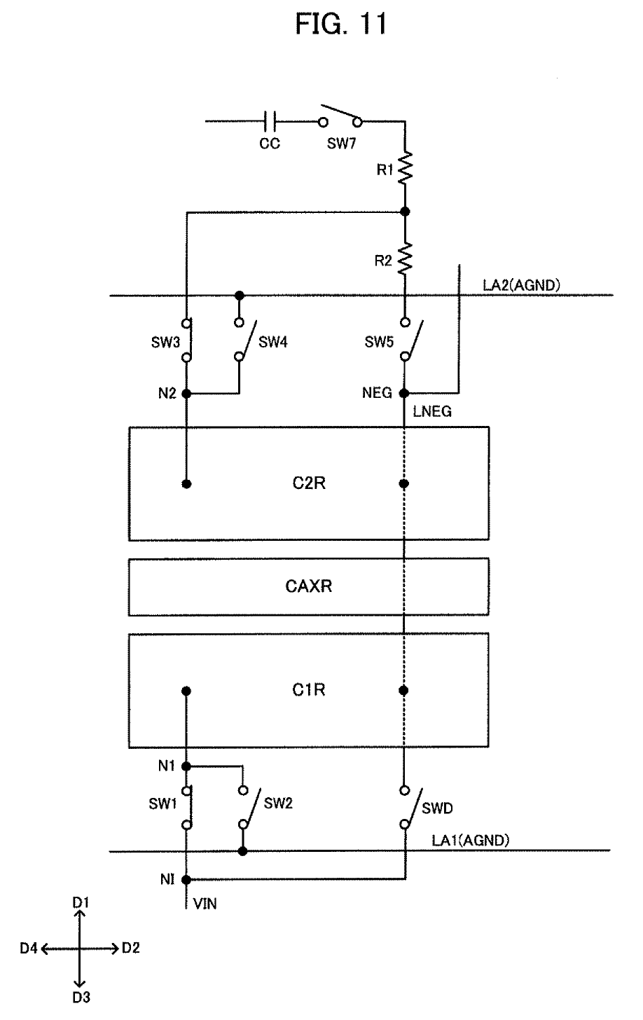

FIG. 11 shows a layout example of the driver circuit according to the modification shown in FIGS. 8 and 9. In FIG. 11, the oscillation prevention resistors R1 and R2, the switch element SW7, and the capacitor CC are disposed in the direction D1 with respect to the switch element SW5, for example. Note that a modification in which the capacitor areas C1R and C2R are disposed along the direction D2 in FIG. 11 is also possible, for example.

In FIG. 11, the switch element SW5 is disposed in the direction D2 with respect to the switch elements SW3 and SW4. A dummy switch element (e.g., a switch element having the same size and shape as those of the switch element SW5) of the switch element SW5 is disposed in the direction D2 with respect to the switch elements SW1 and SW2.

According to this design, a layout that is line-symmetrical with respect to a symmetry axis that passes between the capacitor areas C1R and C2R along the direction D2 can be implemented in the area inside the lines LA1 and LA2. Therefore, the difference CPD in parasitic capacitance can be further reduced so that the circuit characteristics can be improved.

In FIG. 11, the auxiliary capacitor CAX that is connected to the reference node NEG and suppresses a change in the output voltage is formed in a capacitor area CAXR between the capacitor areas C1R and C2R. According to this design, the capacitors C1, C2, and CAX can be efficiently arranged while implementing a line-symmetrical layout.

FIG. 6B shows a specific example of the layout of the capacitor areas C1R, C2R, and CAXR. As shown in FIG. 6B, a plurality of auxiliary unit capacitors CA1 to CA5 that form the auxiliary capacitor CAX are disposed in the capacitor area CAXR.

According to this layout, the auxiliary unit capacitors CA1 to CA5 are disposed in the direction D1 with respect to the unit capacitors C11 to C15 that form the capacitor C1 and are disposed in the direction D3 with respect to the unit capacitors C21 to C25 that form the capacitor C2. Specifically, the unit capacitors C11 to C15 are disposed between the dummy unit capacitors CD1 to CD5 and the auxiliary unit capacitors CA1 to CA5, and the unit capacitors C21 to C25 are disposed between the dummy unit capacitors CD6 to CD10 and the auxiliary unit capacitors CA1 to CA5. Therefore, since the unit capacitors can be arranged line-symmetrically with respect to the symmetry axis that passes between the capacitor areas C1R and C2R along the direction D2, deterioration in circuit characteristics can be prevented.

4. Integrated Circuit Device

An example in which the driver circuit according to this embodiment is applied to a data driver that drives a data line of a display panel (electro-optical device) is described below.

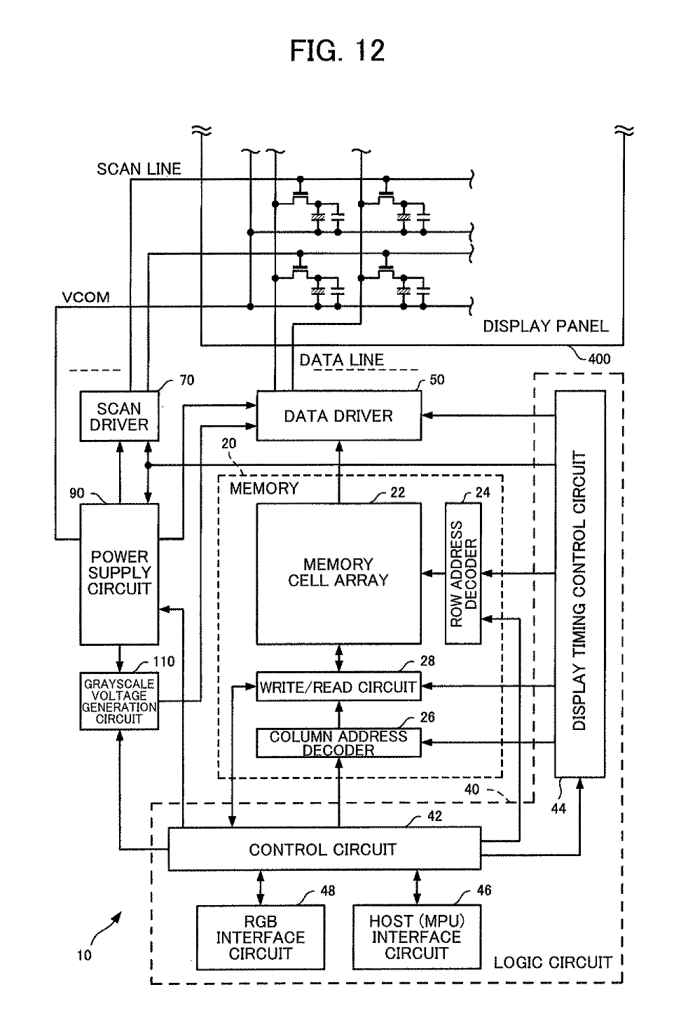

FIG. 12 shows a circuit configuration example of an integrated circuit device 10 (display driver) including a data driver according to one embodiment of the invention. Note that the integrated circuit device 10 according to this embodiment is not limited to the configuration shown in FIG. 12. Various modifications may be made such as omitting some of the elements or adding other elements.

A display panel 400 (electro-optical device in a broad sense) includes a plurality of data lines (source lines), a plurality of scan lines (gate lines), and a plurality of pixels specified by the data lines and the scan lines. A display operation is implemented by changing the optical properties of an electro-optical element (liquid crystal element in a narrow sense) in each pixel area. The display panel may be implemented by an active matrix panel using a switch element such as a TFT or a TFD, for example. Note that the display panel may be a panel other than the active matrix panel, or may be a panel (e.g., organic EL panel) other than the liquid crystal panel.

A memory 20 (display data RAM) stores image data. A memory cell array 22 includes a plurality of memory cells, and stores image data (display data) corresponding to at least one frame (one screen). A row address decoder 24 (MPU/LCD row address decoder) decodes a row address, and selects a wordline of the memory cell array 22. A column address decoder 26 (MPU column address decoder) decodes a column address, and selects a bitline of the memory cell array 22. A write/read circuit 28 (MPU write/read circuit) writes image data into the memory cell array 22, or reads image data from the memory cell array 22.

A logic circuit 40 (driver logic circuit) generates a control signal for controlling a display timing, a control signal for controlling a data processing timing, and the like. The logic circuit 40 may be formed by automatic placement and routing (e.g., gate array (G/A)), for example.

A control circuit 42 generates various control signals, and controls the entire device. Specifically, the control circuit 42 outputs grayscale adjustment data (gamma correction data) for adjusting grayscale characteristics (gamma characteristics) to a grayscale voltage generation circuit 110, or outputs power supply adjustment data for adjusting a power supply voltage to a power supply circuit 90. The control circuit 42 also controls a memory write/read process using the row address decoder 24, the column address decoder 26, and the write/read circuit 28.

A display timing control circuit 44 generates various control signals for controlling the display timing, and controls reading of image data from the memory 20 into the display panel. A host (MPU) interface circuit 46 implements a host interface that generates an internal pulse corresponding to each access from a host and accesses the memory 20. An RGB interface circuit 48 implements an RGB interface that writes motion picture RGB data into the memory 20 based on a dot clock signal. Note that the integrated circuit device 10 may be configured to include only one of the host interface circuit 46 and the RGB interface circuit 48.

A data driver 50 is a circuit that generates a data signal for driving the data line of the display panel. Specifically, the data driver 50 receives image data (grayscale data or display data) from the memory 20, and receives a plurality of (e.g., 256-stage) grayscale voltages (reference voltages) from the grayscale voltage generation circuit 110. The data driver 50 selects a voltage corresponding to the image data (grayscale data) from the plurality of grayscale voltages, and outputs the selected voltage to the data line of the display panel.

A scan driver 70 is a circuit that generates a scan signal for driving the scan line of the display panel. Specifically, the scan driver 70 sequentially shifts a signal (enable input-output signal) using a built-in shift register, and outputs a signal obtained by converting the level of the shifted signal to each scan line of the display panel as the scan signal (scan voltage). The scan driver 70 may include a scan address generation circuit and an address decoder. The scan address generation circuit may generate and output a scan address, and the address decoder may decode the scan address to generate the scan signal.

The power supply circuit 90 is a circuit that generates various power supply voltages. Specifically, the power supply circuit 90 increases an input power source voltage or an internal power supply voltage by a charge-pump method using a boost capacitor and a boost transistor included in a voltage booster circuit provided in the power supply circuit 90. The power supply circuit 90 supplies the resulting voltages to the data driver 50, the scan driver 70, the grayscale voltage generation circuit 110, and the like.

The grayscale voltage generation circuit 110 (gamma correction circuit) is a circuit that generates the grayscale voltage and supplies the grayscale voltage to the data driver 50. Specifically, the grayscale voltage generation circuit 110 may include a ladder resistor circuit that divides the voltage between a high-potential-side voltage and a low-potential-side voltage using resistors, and outputs the grayscale voltages to resistance division nodes. The grayscale voltage generation circuit 110 may also include a grayscale register section into which the grayscale adjustment data is written, a grayscale voltage setting circuit that variably sets (controls) the grayscale voltage output to the resistance division node based on the grayscale adjustment data written into the grayscale register section, and the like.

5. Data Driver

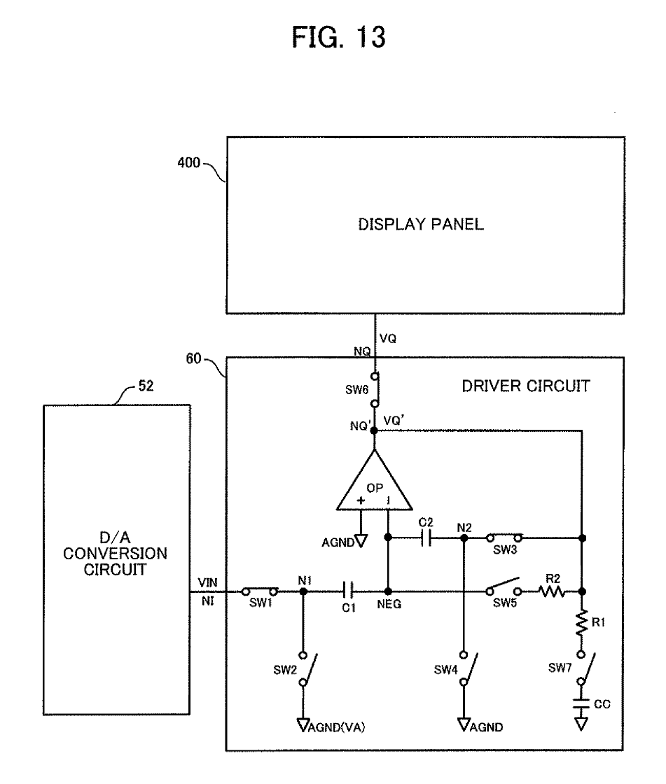

FIG. 13 shows a configuration example of the data driver (source driver) according to this embodiment. The data driver drives the data line of the display panel 400 (electro-optical device) such as a liquid crystal panel. The data driver includes a D/A conversion circuit 52 and the driver circuit 60. The driver circuit 60 and the like may be provided corresponding to each data line of the display panel 400, or the driver circuit 60 may drive a plurality of data lines by time division (multiplex drive). Part or the entirety of the data driver (integrated circuit device) may be integrally formed on the display panel 400.

The D/A conversion circuit 52 (voltage generation circuit) receives grayscale data DG (image data or display data) from the memory 20 shown in FIG. 12, for example. The D/A conversion circuit 52 outputs the input voltage VIN (i.e., a grayscale voltage corresponding to the grayscale data).

Specifically, the D/A conversion circuit 52 receives a plurality of grayscale voltages from the grayscale voltage generation circuit 110 shown in FIG. 12 through grayscale voltage lines. The D/A conversion circuit 52 selects the voltage corresponding to the grayscale data from the plurality of grayscale voltages, and outputs the selected voltage as the input voltage VIN.

The driver circuit 60 receives the input voltage VIN (i.e., the grayscale voltage output from the D/A conversion circuit 52). The driver circuit 60 outputs the output voltage VQ to drive the data line of the display panel 400. As the driver circuit 60, a driver circuit having the configuration described with reference to FIGS. 1, 2, 8, 9, and the like can be applied.

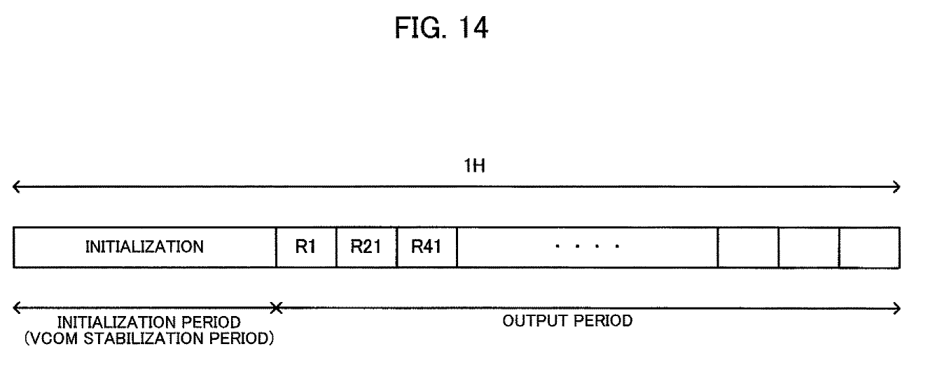

FIG. 14 is a view illustrative of the operation of the data driver according to this embodiment. In FIG. 14, a VCOM stabilization period at the head of a horizontal scan period (1H) corresponds to the initialization period described with reference to FIGS. 1 and 8. The driver circuit 60 drives a plurality of data lines by time division (multiplex drive) after the initialization period.

The VCOM stabilization period is a period in which a common voltage VCOM (common electrode voltage) supplied to a common electrode of pixels is stabilized. For example, when performing line inversion drive, the polarity of a voltage applied to a liquid crystal element is reversed every scan period. Therefore, a positive common voltage VCOM (VCOMH) or a negative common voltage VCOM (VCOML) are selectively output to the common electrode corresponding to each scan period. The VCOM stabilization period is a period required for stabilizing a change due to the VCOM polarity inversion operation.

In the VCOM stabilization period, the data line cannot be driven appropriately even if a voltage is supplied to the data line. In FIG. 14, the driver circuit is initialized by effectively utilizing the VCOM stabilization period. A transition from the initialization period to the output period occurs after the common voltage VCOM has been stabilized to multiplex-drive the data lines. This makes it possible to efficiently drive the data lines.

In the VCOM stabilization period, the data lines may be set at the common voltage VCOM (common potential), for example. According to this configuration, since the data lines of the display panel 400 are charged and discharged by recycling a charge stored in the display panel 400, power consumption can be reduced.

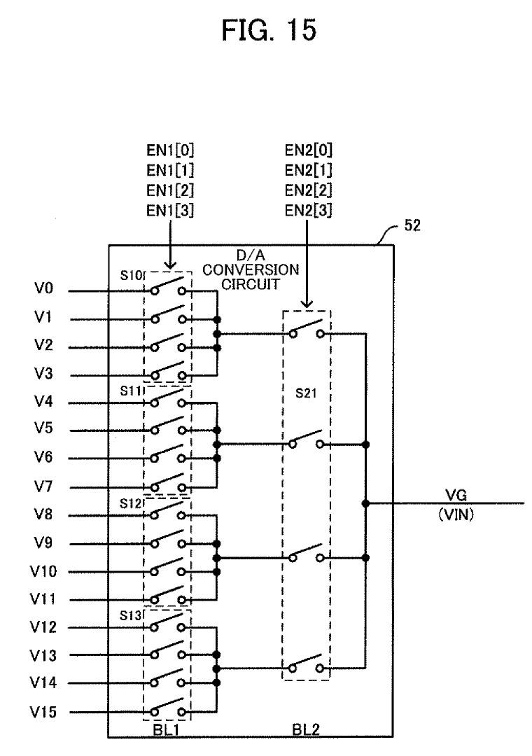

FIG. 15 shows a configuration example of the D/A conversion circuit 52. The D/A conversion circuit 52 shown in FIG. 15 includes multi-stage selector blocks BL1 and BL2, the output from a selector included in the selector block in the preceding stage being input to a selector included in the selector block in the subsequent stage. The number of stages of the selector blocks is not limited to two employed in FIG. 15, but may be three or more.

The D/A conversion circuit 52 shown in FIG. 15 selects one grayscale voltage from a plurality of grayscale voltages by a tournament method, and outputs the selected grayscale voltage as a grayscale voltage VG (VIN). For example, the first-stage selector block is formed by four-input selectors S10 to S13. The grayscale voltages V0 to V15 generated by the grayscale voltage generation circuit 110 shown in FIG. 12 are input to the four-input selectors S10 to S13. The second-stage selector block is formed by a four-input selector S21. The output voltages of the four-input selectors S10 to S13 in the preceding stage are input to the four-input selector S21. The four-input selector S21 outputs the selected grayscale voltage VG (VIN). In this case, the selectors S10 to S13 are controlled based on selector control signals EN1[3] to EN1[0] generated based on the grayscale data. The selector S21 is controlled based on selector control signals EN2[3] to EN2[0] generated based on the grayscale data.

FIG. 15 shows an example in which the number of grayscales is 16 (V0 to V15). Note that the number of grayscales is not limited to 16, but may be 64, 128, 256, or the like.

6. Electronic Instrument

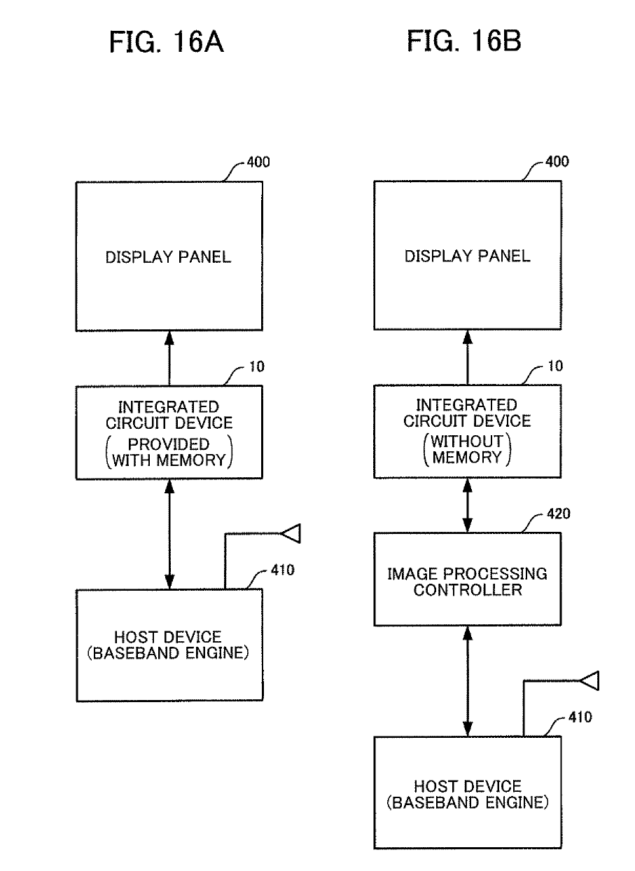

FIGS. 16A and 16B show configuration examples of an electronic instrument (electro-optical device) including the integrated circuit device 10 according to the above embodiment. Note that various modifications may be made such as omitting some of the elements shown in FIGS. 16A and 16B or adding other elements (e.g., camera, operation section, or power supply). The electronic instrument according to this embodiment is not limited to a portable telephone, but may be a digital camera, a PDA, an electronic notebook, an electronic dictionary, a projector, a rear-projection television, a portable information terminal, or the like.

In FIGS. 16A and 16B, a host device 410 is an MPU, a baseband engine, or the like. The host device 410 controls the integrated circuit device 10 (i.e., display driver). The host device 410 may also perform a process of an application engine or a baseband engine, or a process (e.g., compression, decompression, or sizing) of a graphic engine. An image processing controller 420 shown in FIG. 16B performs a process (e.g., compression, decompression, or sizing) of a graphic engine instead of the host device 410.

In FIG. 16A, the integrated circuit device 10 may include a memory. In this case, the integrated circuit device 10 writes image data from the host device 410 into the built-in memory, reads the image data from the built-in memory, and drives the display panel. In FIG. 16B, the integrated circuit device 10 may not include a memory. In this case, image data output from the host device 410 is written into a built-in memory of the image processing controller 420. The integrated circuit device 10 drives the display panel 400 under control of the image processing controller 420.

Although some embodiments of the invention have been described in detail above, those skilled in the art would readily appreciate that many modifications are possible in the embodiments without materially departing from the novel teachings and advantages of the invention. Accordingly, such modifications are intended to be included within the scope of the invention. Any term (e.g., display panel, inverting input terminal, non-inverting input terminal, and AGND) cited with a different term (e.g., electro-optical device, first input terminal, second input terminal, and analog reference power supply) having a broader meaning or the same meaning at least once in the specification and the drawings can be replaced by the different term in any place in the specification and the drawings. The configurations and the operations of the driver circuit, the data driver, the D/A conversion circuit, the integrated circuit device, the electronic instrument, and the like are not limited to those described with reference to the above embodiments. Various modifications and variations may be made. The drive target of the driver circuit according to the above embodiments is not limited to the data line.

What is claimed is:

1. A driver circuit that receives an input voltage and outputs an output voltage, the driver circuit comprising:
a first capacitor provided between a first node and a reference node;
a first switch element provided between the first node and an input node of the input voltage;
a second switch element provided between the first node and an analog reference power supply;
a second capacitor provided between a second node and the reference node;
a third switch element provided between the second node and an output node of the output voltage;
a fourth switch element provided between the second node and the analog reference power supply; and
a fifth switch element provided between the output node and the reference node,
a first capacitor area and a second capacitor area being disposed along a first direction, the first capacitor being formed in the first capacitor area, and the second capacitor being formed in the second capacitor area;
the first switch element and the second switch element being disposed in a third direction with respect to the first capacitor area and the second capacitor area, the third direction being a direction opposite to the first direction;
the third switch element and the fourth switch element being disposed in the first direction with respect to the first capacitor area and the second capacitor area; and
a reference node line that is a line of the reference node being provided in a second direction with respect to the first switch element, the second switch element, the third switch element, and the fourth switch element, the second direction being a direction that perpendicularly intersects the first direction.

2. The driver circuit as defined in claim 1, further comprising:
a first analog reference power supply line provided along the second direction in the third direction with respect to the first capacitor area and the second capacitor area, the first analog reference power supply line supplying a voltage supplied from the analog reference power supply to the second switch element; and
a second analog reference power supply line provided along the second direction in the first direction with respect to the first capacitor area and the second capacitor area, the second analog reference power supply line supplying the voltage supplied from the analog reference power supply to the fourth switch element.

3. The driver circuit as defined in claim 1,
the second switch element, the fourth switch element, and the fifth switch element being turned ON in an initialization period; and
the first switch element and the third switch element being turned ON in an output period of the output voltage.

4. The driver circuit as defined in claim 1, further comprising:
an operational amplifier that outputs the output voltage to the output node, a first input terminal of the operational amplifier being connected to the reference node, and a second input terminal of the operational amplifier being set at a voltage supplied from the analog reference power supply.

5. The driver circuit as defined in claim 4, further comprising:
an oscillation prevention capacitor, one end of the oscillation prevention capacitor being electrically connected to the output node of the operational amplifier in an initialization period to prevent oscillation of the operational amplifier.

6. The driver circuit as defined in claim 1,
the fifth switch element being disposed in the second direction with respect to the third switch element and the fourth switch element; and
a dummy switch element of the fifth switch element being disposed in the second direction with respect to the first switch element and the second switch element.

7. The driver circuit as defined in claim 1, further comprising:
an auxiliary capacitor, one end of the auxiliary capacitor being connected to the reference node,
the auxiliary capacitor being formed in a capacitor area between the first capacitor area and the second capacitor area.

8. A driver circuit that receives an input voltage and outputs an output voltage, the driver circuit comprising:
a first capacitor, one end of the first capacitor being connected to a reference node, and the other end of the first capacitor being set at a voltage supplied from an analog reference power supply in an initialization period and set at the input voltage in an output period; and
a second capacitor, one end of the second capacitor being connected to the reference node, and the other end of the second capacitor being set at the voltage supplied from the analog reference power supply in the initialization period and set at the output voltage in the output period,
a reference node line that is a line of the reference node being provided along a first direction;
a first analog reference power supply line being provided along a second direction in a third direction with respect to a first capacitor area and a second capacitor area, the first analog reference power supply line supplying the voltage supplied from the analog reference power supply to the other end of the first capacitor, a direction that perpendicularly intersects the first direction being referred to as the second direction and a direction opposite to the first direction being referred to as the third direction; and
a second analog reference power supply line being provided along the second direction in the first direction with respect to the first capacitor area and the second capacitor area, the second analog reference power supply line supplying the voltage supplied from the analog reference power supply to the other end of the second capacitor.

9. A data driver that drives a data line of an electro-optical device, the data driver comprising:
a D/A conversion circuit that receives grayscale data and outputs a grayscale voltage corresponding to the grayscale data; and
the driver circuit as defined in claim 1 that receives the grayscale voltage output from the D/A conversion circuit as the input voltage, and outputs the output voltage to the data line.

10. A data driver that drives a data line of an electro-optical device, the data driver comprising:
a D/A conversion circuit that receives grayscale data and outputs a grayscale voltage corresponding to the grayscale data; and
the driver circuit as defined in claim 8 that receives the grayscale voltage output from the D/A conversion circuit as the input voltage, and outputs the output voltage to the data line.

11. An integrated circuit device comprising the data driver as defined in claim 9.

12. An integrated circuit device comprising the data driver as defined in claim 10.

13. An electronic instrument comprising the integrated circuit device as defined in claim 11.

14. An electronic instrument comprising the integrated circuit device as defined in claim 12.
